(19) United States
(12) Patent Application Publication
(10) Pub. No.: US 2017/0045552 A1
(43) Pub. Date: Feb. 16, 2017

(54) PROBE

(71) Applicant: CHROMA ATE INC., Taoyuan (TW)

(72) Inventors: Mao-Sheng LIU, Taoyuan (TW); Hsiu-Wei KUO, Taoyuan (TW); Chao-Hsu CHEN, Taoyuan (TW)

(73) Assignee: CHROMA ATE INC., Taoyuan (TW)

(21) Appl. No.: 15/195,794

(22) Filed: Jun. 28, 2016

(30) Foreign Application Priority Data
Aug. 14, 2015 (CN) 201510500486.X

(51) Int. Cl. G01R 1/067; G01R 31/36

(52) U.S. Cl. CPC G01R 1/06722; G01R 31/3644

(57) ABSTRACT

A probe includes a first electrical conductor, a second electrical conductor and a voltage measurer. The first electrical conductor has a first through hole, and the first through hole extends through two ends of the first electrical conductor. The second electrical conductor is detachably disposed on the first electrical conductor, and the second electrical conductor has a working surface and a second through hole. The working surface is located at an end of the second electrical conductor away from the first electrical conductor. Two ends of the second through hole that are opposite to each other are located at the working surface and an end of the first through hole, respectively. The first through hole is communicated with the second through hole. The voltage measurer is penetrating through the first through hole and the second through hole.

### CROSS-REFERENCE TO RELATED APPLICATIONS

This non-provisional application claims priority under 35 U.S.C. §119(a) on Patent Application No(s). 201510500486.X filed in China on Aug. 14, 2015, the entire contents of which are hereby incorporated by reference.

### TECHNICAL FIELD

The disclosure relates to a probe, more particularly to a detachable probe.

### BACKGROUND

An electrical property test, such as a charging-capability test of a car battery, is performed by a probe for checking the reliability and the yield of an electronic component before shipment. Take the charging-capability test of the car battery as an example, electrifying a probe that is electrically connected to an electrode of the car battery so that the probe can measure a voltage across the electrode.

### SUMMARY

According to the disclosure, a probe includes a first electrical conductor, a second electrical conductor and a voltage measurer. The first electrical conductor has a first through hole, and the first through hole extends through two ends of the first electrical conductor. The second electrical conductor is detachably disposed on the first electrical conductor, and the second electrical conductor has a working surface and a second through hole. The working surface is located at an end of the second electrical conductor away from the first electrical conductor. Two ends of the second through hole that are opposite to each other are located at the working surface and an end of the first through hole, respectively. The first through hole is communicated with the second through hole. The voltage measurer penetrates through the first through hole and the second through hole.

### BRIEF DESCRIPTION OF THE DRAWINGS

The present invention will become better understood from the detailed description given hereinbelow and the accompanying drawings which are given by way of illustration only and thus are not limitative of the present invention and wherein:

FIG. 1 is a perspective view of a probe according to a first embodiment;

FIG. 2 is a cross-sectional view of the probe in FIG. 1;

FIG. 3A is an exploded view of the probe in FIG. 1;

FIG. 3B is an enlarged view of a second electrical conductor of the probe in FIG. 1;

FIG. 4 is a cross-sectional view of a probe according to a second embodiment; and

FIG. 5 is a cross-sectional view of a probe according to a third embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

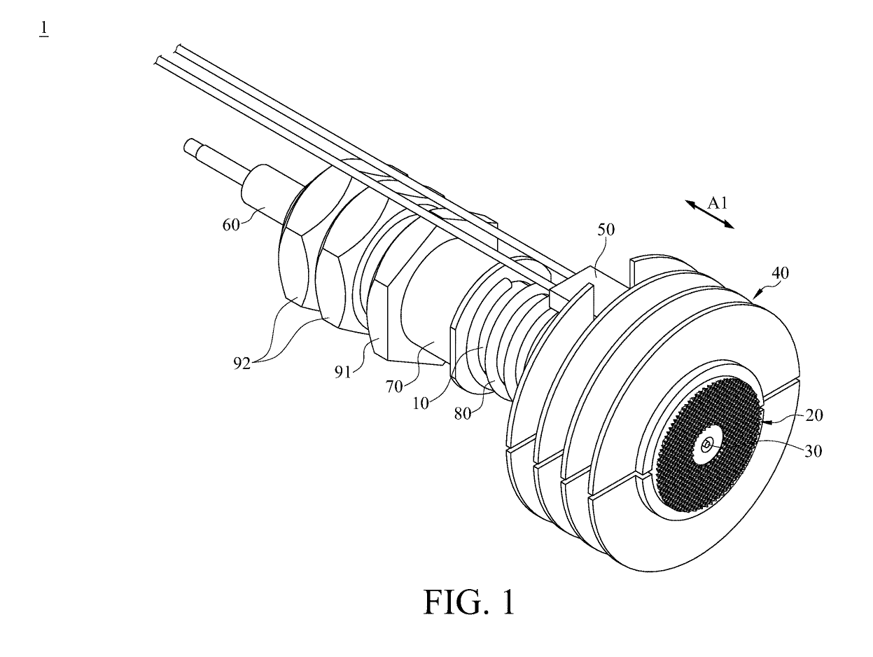

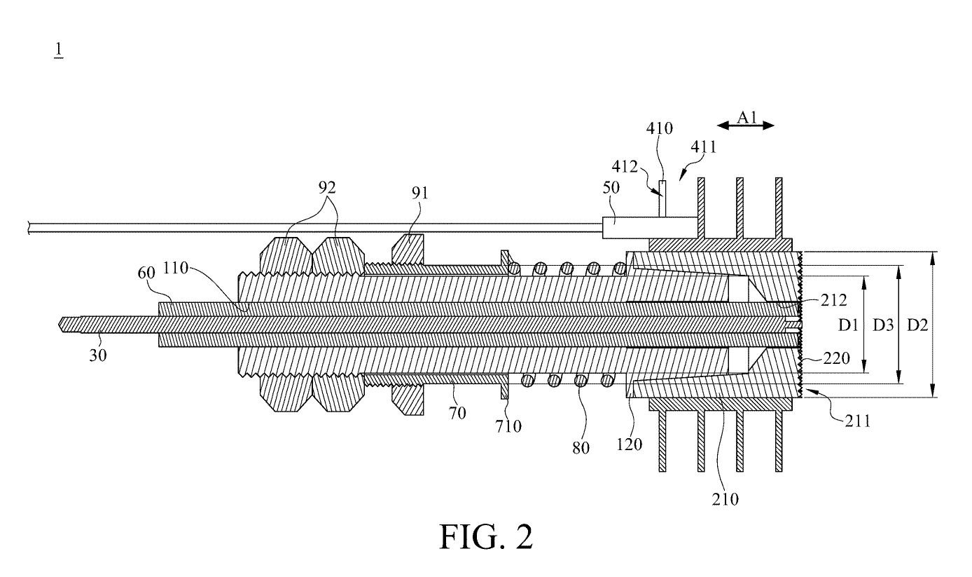

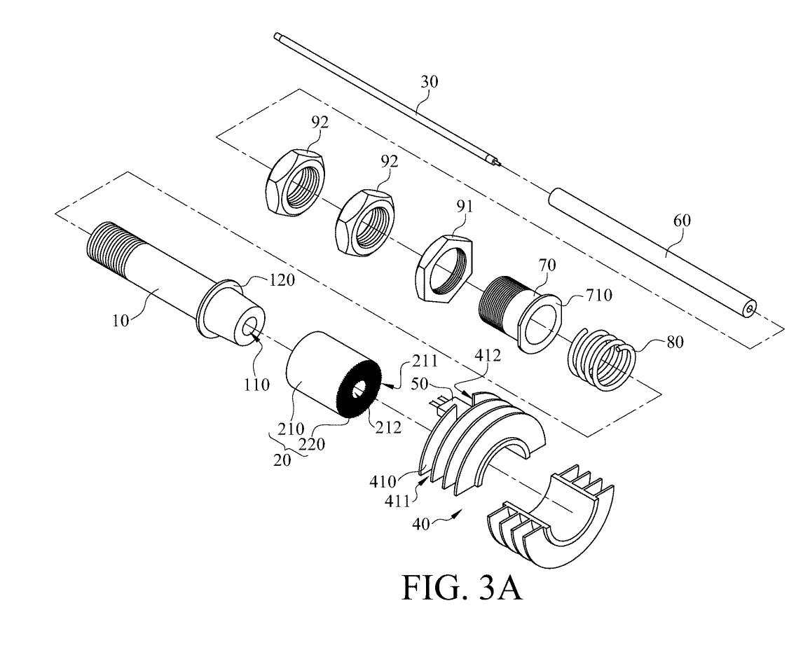

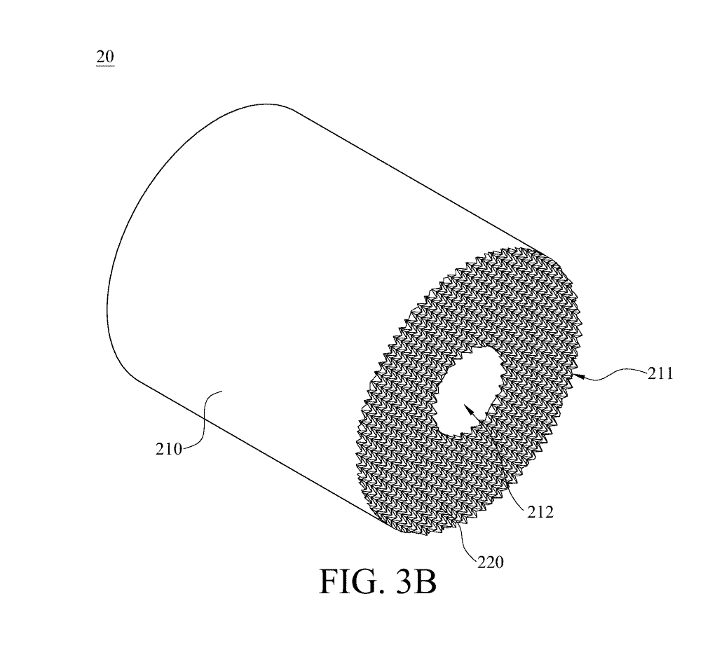

Please refer to FIG. 1 to FIG. 3B. FIG. 1 is a perspective view of a probe according to a first embodiment. FIG. 2 is a cross-sectional view of the probe in FIG. 1. FIG. 3A is an exploded view of the probe in FIG. 1. FIG. 3B is an enlarged view of a second electrical conductor of the probe in FIG. 1.

In this embodiment, a probe 1 includes a first electrical conductor 10, a second electrical conductor 20 and a voltage measurer 30. The first electrical conductor 10 is a main body of the probe 1, and the second electrical conductor 20 is a head of the probe 1. Each of the first electrical conductor 10, the second electrical conductor 20 and the voltage measurer 30 is made of conductive material.

The first electrical conductor 10 has a first through hole 110. The first through hole 110 extends through two ends of the first electrical conductor 10. That is, two ends of the first through hole 110 that are opposite to each other are located at the two ends of the first electrical conductor 10, respectively.

The second electrical conductor 20 is detachably disposed on the first electrical conductor 10. In detail, the second electrical conductor 20 includes an assembling part 210 and a plurality of cones 220. The assembling part 210 has a working surface 211 and a second through hole 212. The working surface 211 is located at an end of the assembling part 210 further away from the first electrical conductor 10 than the other end of the assembling part 210. Two ends of the second through hole 212 that are opposite to each other are located at the working surface 211 and an end of the first through hole 110 facing the assembling part 210, respectively. The first through hole 110 is communicated with the second through hole 212. The cones 220 are fixed on the working surface 211. A base of the cone 220 is toward the working surface 211, and a vertex of the cone 220 is backward the working surface 211. An electrical current is capable of passing through the assembling part 210 to flow out of the second electrical conductor 20 from the vertices of the cones 220. In this embodiment, the second electrical conductor 20 is tightly fitted to the first electrical conductor 10, but the disclosure is not limited thereto. In other embodiments, the second electrical conductor 20 can be screwed to or locked to the first electrical conductor 10. Furthermore, the second electrical conductor 20 includes the cones 220 in this embodiment, but the disclosure is not limited thereto. In other embodiments, the second electrical conductor 20 can have no cones 220 so that the electrical current flows out of the second electrical conductor 20 from the working surface 211.

The voltage measurer 30 penetrates through the first through hole 110 and the second through hole 212. That is, a part of the voltage measurer 30 is located in the first through hole 110, and a part of the voltage measurer 30 is located in the second through hole 212.

In this embodiment, the first electrical conductor 10 is electrically connected to a cable (not shown in the drawings), and the assembling part 210 is detachably disposed on the first electrical conductor 10. The cones 220 and the voltage measurer 30 are for being abutted against a sample (not shown in the drawings), and the voltage measurer 30 is electrically connected to a voltmeter (not shown in the drawings). The sample, for example, is an electrode of a car battery or a metal pad on a semiconductor chip. When the electrical current flows from the cable into the first electrical conductor 10, the electrical current sequentially passes through the first electrical conductor 10, the working surface 211 of the assembling part 210 and the cones 220; thereby, the electrical current flows into the sample from the cones 220. The voltage measurer 30 is for measuring a voltage across the sample. A resistance of the sample is generated by calculating the ratio of the across the sample to the current through the sample.

According to this embodiment of the disclosure, the second electrical conductor 20 is detachably disposed on the first electrical conductor 10. Therefore, it is convenient for a user to rapidly replace the damaged second electrical conductor 20 with a new second electrical conductor 20 so that the cost for repairing the probe 1 is reduced, and the maintenance efficiency is also improved.

In addition to the aforementioned description, the probe 1 in this embodiment can be characterized by some features illustrated hereafter for the improvement of the usefulness.

The probe 1 can include a fin set 40 and a temperature sensor 50. The fin set 40 is disposed on the second electrical conductor 20, and the temperature sensor 50 is disposed on the fin set 40. In detail, the fin set 40 surrounds the assembling part 210 of the second electrical conductor 20, and the fin set 40 includes a plurality of fins 410 arranged along an axis A1 (axial direction) of the second electrical conductor 20. Every two of the fins 410 that are adjacent to each other are spaced apart. That is, there is a gap 411 between every two of the adjacent fins 410. One of the fins 410 has a recess 412 located at an outer edge of the fin 410. At least a part of the temperature sensor 50 is located in the recess 412, and a part of the temperature sensor 50 extends into the gaps 411 next to the recess 412. The temperature sensor 50 is for monitoring the temperature of the fin set 40. Therefore, the fin set 40 is favorable for dissipating the heat generated from the second electrical conductor 20 so as to prevent the second electrical conductor 20 from damage due to overheating. The temperature sensor 50 is located in the recess 412 so as to keep the probe 1 compact.

Furthermore, the probe 1 can include an insulator 60. As shown in FIG. 2, the insulator 60 is interposed between the first electrical conductor 10 and the voltage measurer 30, and the insulator 60 is interposed between the second electrical conductor 20 and the voltage measurer 30. The first electrical conductor 10 and the second electrical conductor 20 are electrically insulated from the voltage measurer 30 by the insulator 60. Therefore, the insulator 60 is favorable for preventing a short circuit between every two of the first electrical conductor 10, the second electrical conductor 20 and the voltage measurer 30; thereby, the voltage measurer 30 is capable of measuring the voltage across the sample more precisely and accurately, and the safety of operating the probe 1 is also improved.

Moreover, the probe 1 can include a sleeve 70, an elastic component 80, a first fastener 91 and two second fasteners 92. The elastic component 80, for example, is a compression spring. The first electrical conductor 10 can include a first protrusion 120 protruding outward from an outer surface of the first electrical conductor 10, and the sleeve 70 can include a second protrusion 710 protruding outward from an outer surface of the sleeve 70. Both the elastic component 80 and the sleeve 70 surround the first electrical conductor 10. The elastic component 80 is located between the first protrusion 120 and the second protrusion 710. Two ends of the elastic component 80 that are opposite to each other are abutted against the first protrusion 120 and the second protrusion 710, respectively. The elastic component 80 is for pressing the first protrusion 120 and the second protrusion 710 so as to drive the first electrical conductor 10 to move relative to the sleeve 70. The first fastener 91 and the second fasteners 92, for example, are a plurality of nuts. The first fastener 91 surrounds the sleeve 70, and the second fasteners 92 surround the first electrical conductor 10. The first fastener 91 includes an internal screw thread, and the sleeve 70 includes an external screw thread corresponding to the internal screw thread of the first fastener 91. The sleeve 70 can be fixed to a circuit board (not shown in the drawings) by the first fastener 91 and the second fasteners 92, and the circuit board can be fixed to a base such as a case of an electrical property testing device (not shown in the drawings). When the sleeve 70 is fixed to the circuit board, both the first electrical conductor 10 and the sleeve 70 are normally pressed by the elastic component 80 so that the cones 220 of the second electrical conductor 20 are normally abutted against the sample during the electrical property test. Therefore, the measurement accuracy and the measurement precision of the current and the voltage are improved. In this embodiment, the sleeve 70 is fixed to the circuit board by the first fastener 91 and the second fasteners 92, but the disclosure is not limited thereto. In other embodiments, the sleeve may be glued to or fitted to the circuit board.

In addition, as shown in FIG. 2, an outer diameter D2 of the second electrical conductor 20 can be larger than an outer diameter D3 of the sleeve 70, and the outer diameter D3 of the sleeve 70 can be larger than an outer diameter D1 of the first electrical conductor 10. In detail, the outer diameter D1 of the first electrical conductor 10 can be 6-10 millimeters (mm), and the outer diameter D2 of the second electrical conductor 20 can be 8-12 mm. Therefore, damages to the probe 1 caused by high electrical current is prevented when a high electrical current is flowing through the probe 1 so that the probe 1 is favorably applied to the electrical property test for large scale electronic equipment. The aforementioned high electrical current is defined as an electrical current which is equal to or larger than 100 ampere (A).

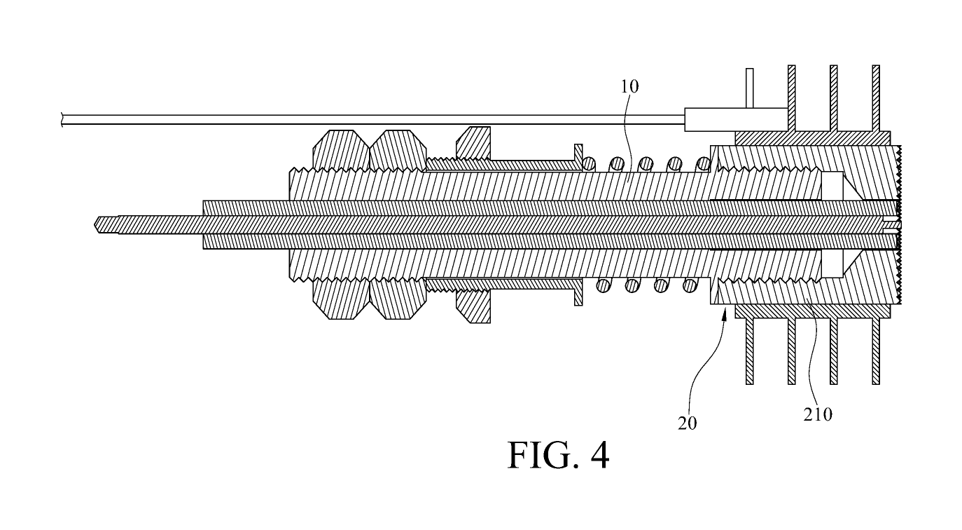

In the first embodiment, the second electrical conductor 20 is fastened to the first electrical conductor 10, but the disclosure is not limited thereto. Please refer to FIG. 4, which is a cross-sectional view of a probe according to a second embodiment. Since the second embodiment is similar to the first embodiment, only the differences will be illustrated hereafter.

In this embodiment, the second electrical conductor 20 is screwed to the first electrical conductor 10. That is, an internal screw thread at the assembling part 210 of the second electrical conductor 20 is screwed to an external screw thread at the first electrical conductor 10. Therefore, the user is able to detach the second electrical conductor 20 from the first electrical conductor 10 by rotating the second electrical conductor 20 to loosen the second electrical conductor 20.

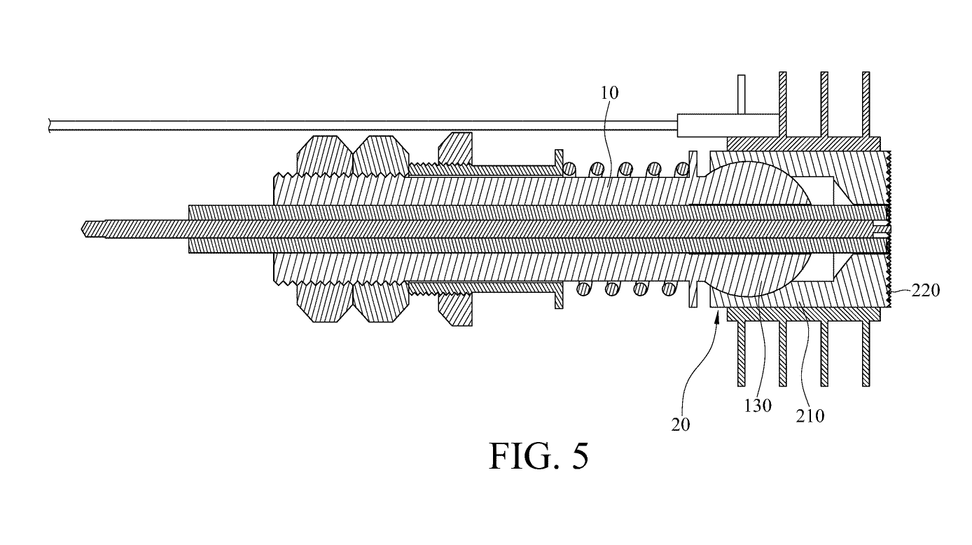

Please refer to FIG. 5, which is a cross-sectional view of a probe according to a third embodiment. Since the third embodiment is similar to the first embodiment, only the differences will be illustrated hereafter.

In this embodiment, the first electrical conductor 10 includes a spherical head 130 at one end of the first electrical conductor 10. The assembling part 210 of the second electrical conductor 20 is tightly fitted to the spherical head 130 so as to be detachably disposed on the first electrical conductor 10. The first electrical conductor 10 and the second electrical conductor 20 are assembled together via the spherical head 130 so that the first electrical conductor 10 is rotatable relative to the second electrical conductor 20. When the first electrical conductor 10 is rotated, the spherical head 130 pushes the cones 220 to be stably abutted against the sample.

According to the disclosure, the second electrical conductor is detachably disposed on the first electrical conductor so that it is favorable for conveniently detaching the damaged second electrical conductor from the first electrical conductor. Furthermore, it is also favorable for rapidly assembling the new second electrical conductor to the first electrical conductor. Therefore, the cost for repairing the probe is reduced, and the maintenance efficiency is also increased.

Moreover, the fin set is favorable for dissipating the heat generated from the second electrical conductor so as to prevent the second electrical conductor from damage due to overheating. The temperature sensor is located in the recess so as to keep the probe compact.

In addition, the insulator is favorable for preventing a short circuit between every two of the first electrical conductors, the second electrical conductors and the voltage measurer. Thereby, the voltage measurer is capable of detecting and measuring the voltage across the sample more precisely and accurately, and the safety of operating the probe is also improved.

In addition, the first electrical conductor and the sleeve are pressed by the elastic component so that the cones of the second electrical conductor are normally abutted against the sample during the electrical property test. Therefore, the measurement accuracy and the measurement precision of the current and the voltage are improved.

What is claimed is:

1. A probe, comprising:
a first electrical conductor having a first through hole, and the first through hole extending through the first electrical conductor;
a second electrical conductor detachably disposed on the first electrical conductor having a working surface and a second through hole, the working surface located at an end of the second electrical conductor away from the first electrical conductor, two ends of the second through hole that are opposite to each other being located at the working surface and the first through hole, respectively; and
a voltage measurer penetrating through the first through hole and the second through hole.

2. The probe according to claim 1, further comprising a fin set disposed on the second electrical conductor.

3. The probe according to claim 2, further comprising a temperature sensor disposed on the fin set.

4. The probe according to claim 3, wherein the fin set surrounds the second electrical conductor, the fin set comprises a plurality of fins arranged along an axial direction of the second electrical conductor, every two of the plurality of fins that are adjacent to each other are spaced apart, one of the plurality of fins has a recess located at an outer edge of the fin, and at least a part of the temperature sensor is located in the recess.

5. The probe according to claim 1, further comprising an insulator interposed between the first electrical conductor and the voltage measurer, and the first electrical conductor being electrically insulated from the voltage measurer by the insulator.

6. The probe according to claim 1, wherein the second electrical conductor comprises an assembling part and a plurality of cones, the working surface is located at the assembling part, the plurality of cones are fixed on the working surface, and each vertex of the cones is backward the working surface.

7. The probe according to claim 1, further comprising a sleeve and an elastic component, wherein the first electrical conductor comprises a first protrusion, the sleeve comprises a second protrusion, the elastic component and the sleeve surround the first electrical conductor, two ends of the elastic component that are opposite to each other are abutted against the first protrusion and the second protrusion, respectively, and the elastic component is for pressing the first electrical conductor to move relative to the sleeve.

8. The probe according to claim 7, wherein the elastic component is a compression spring.

9. The probe according to claim 7, further comprising a fastener surrounding the sleeve, wherein the fastener comprises an internal screw thread, the sleeve comprises an external screw thread corresponding to the internal screw thread, and the sleeve is fixed to a circuit board by the fastener.

10. The probe according to claim 7, wherein an outer diameter of the second electrical conductor is larger than an outer diameter of the sleeve, and the outer diameter of the sleeve is larger than an outer diameter of the first electrical conductor.
